(19) United States
(12) Patent Application Publication
(10) Pub. No.: US 2026/0096081 A1
(43) Pub. Date: Apr. 2, 2026

(54) SEMICONDUCTOR MEMORY DEVICE

(71) Applicant: Socionext Inc., Kanagawa (JP)

(72) Inventor: Masanobu HIROSE, Yokohama-shi (JP)

(21) Appl. No.: 19/413,805

(22) Filed: Dec. 9, 2025

Related U.S. Application Data
(63) Continuation of application No. PCT/JP2024/020652, filed on Jun. 6, 2024.

(30) Foreign Application Priority Data
Jun. 26, 2023 (JP) 2023-104373

(51) Int. Cl. H10B 10/00

(52) U.S. Cl. CPC H10B 10/125

(57) ABSTRACT

Lines corresponding to bit lines BLB and BL are formed in a metal interconnect layer. An SRAM cell includes: a power supply line formed in a first back interconnect layer on a back side of transistors, the power supply line having portions overlapping active regions in plan view and supplying a power supply voltage VDD; a power supply line formed in the first back interconnect layer, the power supply line having a portion overlapping an active region in plan view and supplying a power supply voltage VSS; and a power supply line formed in the first back interconnect layer, the power supply line having a portion overlapping an active region in plan view and supplying a power supply voltage VSS.

### CROSS-REFERENCE TO RELATED APPLICATIONS

This is a continuation of International Application No. PCT/JP2024/020652 filed on June 6, 2024, which claims priority to Japanese Patent Application No. 2023-104373 filed on June 26, 2023. The entire disclosures of these applications are incorporated by reference herein.

### BACKGROUND

The present disclosure relates to a semiconductor memory device, particularly a layout structure of a static random access memory (SRAM) cell (hereinafter also simply referred to as a “cell” as appropriate).

SRAMs have been widely used for semiconductor integrated circuits.

Further, the gate length of a transistor which is a basic component of an LSI has been reduced (scaling) to improve integration degree, reduce the operating voltage, and improve the operating speed. However, an off-current due to excessive scaling and a significant increase in power consumption due to the off-current have been concerned in recent years. To address these concerns, studies have been actively conducted for a transistor having a three-dimensional structure in which a configuration of a transistor is changed from a traditional planar type to a three-dimensional type. An example of the transistor having a three-dimensional structure is a nanosheet field effect transistor (FET).

United States Patent Application Publication No. 2022/0336474 discloses providing a word line on the back of a substrate immediately below a transistor, for higher integration.

### SUMMARY

Here, according to the technique of United States Patent Application Publication No. 2022/0336474, the line width of a bit line cannot be increased because the bit line and the power supply line are provided in the same interconnect layer. This increases the line resistance of the bit line and lowers the operating speed of the semiconductor memory device. Since the bit line and the power supply line are provided in the same interconnect layer, the line width of the power supply line cannot be increased either. This increases the line resistance of the power supply line and causes a greater drop in the power supply voltage, lowering the operating speed of the semiconductor memory device. Further, since the distance between the bit line and the power supply line is close, the parasitic capacitance increases, lowering the operating speed of the semiconductor memory device.

Since the word line is provided on the back of the substrate, a connector for connecting the line on the back and the line on the front is required so that the word line be connected to the line on the front of the substrate in a peripheral circuit. This increases the area of the semiconductor memory device and lowers the operating speed of the semiconductor memory device due to the resistance of the connector.

It is an object of the present disclosure to provide a layout structure of an SRAM cell with a line on the back of a transistor, which can reduce an increase in the area of a semiconductor memory device, while reducing lowering of the operating speed of the semiconductor memory device.

A first aspect of the present disclosure is a semiconductor memory device including an SRAM cell. The SRAM cell includes: a first transistor having a source connected to a first power source for supplying a first power supply voltage, a drain connected to a first node, and a gate connected to a second node; a second transistor having a source connected to the first power source, a drain connected to the second node, and a gate connected to the first node; a third transistor having a source connected to a second power source for supplying a second power supply voltage different from the first power supply voltage, a drain connected to the first node, and a gate connected to the second node; a fourth transistor having a source connected to the second power source, a drain connected to the second node, and a gate connected to the first node; a fifth transistor having a source connected to a first bit line, a drain connected to the first node, and a gate connected to a word line; and a sixth transistor having a source connected to a second bit line forming a complementary bit line pair together with the first bit line, a drain connected to the second node, and a gate connected to the word line, the first bit line including a first line formed in a metal interconnect layer above the first to sixth transistors, the first line extending in a first direction, the second bit line including a second line formed in the metal interconnect layer, the second line extending in the first direction, the SRAM cell including: a first active region forming a channel, the source, and the drain of the first transistor, and including a nanosheet extending in the first direction as the channel; a second active region forming a channel, the source, and the drain of the second transistor, and including a nanosheet extending in the first direction as the channel; a third active region forming a channel, the source, and the drain of the third transistor, and including a nanosheet extending in the first direction as the channel; a fourth active region forming a channel, the source, and the drain of the fourth transistor, and including a nanosheet extending in the first direction as the channel; a first power supply line formed in a first back interconnect layer on a back side of the first to sixth transistors, the first power supply line extending in the first direction, including a portion overlapping the first active region and the second active region in plan view, and connected to the first power source; a second power supply line formed in the first back interconnect layer, the second power supply line extending in the first direction, including a portion overlapping the third active region in plan view, and connected to the second power source; a third power supply line formed in the first back interconnect layer, the third power supply line extending in the first direction, including a portion overlapping the fourth active region in plan view, and connected to the second power source; a first via arranged at a position where a first region forming the source in the first active region and the first power supply line overlap each other, the first via connecting the first region and the first power supply line; a second via arranged at a position where a second region forming the source in the second active region and the first power supply line overlap each other, the second via connecting the second region and the first power supply line; a third via arranged at a position where a third region forming the source in the third active region and the second power supply line overlap each other, the third via connecting the third region and the second power supply line; and a fourth via arranged at a position where a fourth region forming the source in the fourth active region and the third power supply line overlap each other, the fourth via connecting the fourth region and the third power supply line.

According to the present disclosure, the first back interconnect layer, which is an interconnect layer on the back side of the transistor, is provided with the first power supply line for supplying the first power supply voltage, and the second and third power supply lines for supplying the second power supply voltage. The metal interconnect layer above the first to sixth transistors is provided with the first and second lines corresponding to the bit lines BLB and BL, respectively. Accordingly, the lines formed in the first back interconnect layer are only the power supply lines. The first power supply line overlaps the first and second active regions in plan view. The second power supply line overlaps the third active region in plan view. The fourth power supply line overlaps the fourth active region in plan view. This configuration allows the power supply lines in the first back interconnect layer to overlap with the active regions in plan view. It is thus possible to increase the line widths of the power supply lines in the first back interconnect layer and reduce the line resistances of the power supply lines, which can reduce lowering of the operating speed of the semiconductor memory device.

Further, since it is not necessary to form power supply lines for supplying the first power supply voltage and the second power supply voltage in the metal interconnect layer, the line widths of the first and second lines corresponding to the first and second bit lines, respectively, can be increased. This can reduce the line resistances of the bit lines and thus can reduce lowering of the operating speed of the semiconductor memory device.

Due to formation of the line, corresponding to the word line, in a layer above the metal interconnect layer, no connector is required in connecting the lines on the back of the transistor and the lines on the front of the transistor (i.e., layer above the transistor), making it possible to reduce lowering of the operating speed of the semiconductor memory device, while reducing an increase in the area of the semiconductor memory device.

A second aspect of the present disclosure is a semiconductor memory device including an SRAM cell. The SRAM cell includes: a first transistor having a source connected to a first power source for supplying a first power supply voltage, a drain connected to a first node, and a gate connected to a second node; a second transistor having a source connected to the first power source, a drain connected to the second node, and a gate connected to the first node; a third transistor having a source connected to a second power source for supplying a second power supply voltage different from the first power supply voltage, a drain connected to the second node, and a gate connected to the second node; a fourth transistor having a source connected to the second power source, a drain connected to the second node, and a gate connected to the first node; a fifth transistor having a source connected to a first bit line, a drain connected to the first node, and a gate connected to a word line; and a sixth transistor having a source connected to a second bit line forming a complementary bit line pair together with the first bit line, a drain connected to the second node, and a gate connected to the word line, the first bit line including a first line formed in a metal interconnect layer above the first to sixth transistors, the first line extending in a first direction, the second bit line including a second line formed in the metal interconnect layer, the second line extending in the first direction, the SRAM cell including: a third active region forming a channel, the source, and the drain of the third transistor, and including a nanosheet extending in the first direction as the channel; a fourth active region forming a channel, the source, and the drain of the fourth transistor, and including a nanosheet extending in the first direction as the channel; a first power supply line formed in the metal interconnect layer, the first power supply line extending in the first direction and connected to the first power source; a second power supply line formed in a first back interconnect layer on a back side of the first to sixth transistors, the second power supply line extending in the first direction, including a portion overlapping the third active region in plan view, and connected to the second power source; a third power supply line formed in the first back interconnect layer, the third power supply line extending in the first direction, including a portion overlapping the fourth active region in plan view, and connected to the second power source; a third via arranged at a position where a third region forming the source in the third active region and the second power supply line overlap each other, the third via connecting the third region and the second power supply line; and a fourth via arranged at a position where a fourth region forming the source in the fourth active region and the third power supply line overlap each other, the fourth via connecting the fourth region and the third power supply line.

According to the present disclosure, the first back interconnect layer, which is an interconnect layer on the back of the transistor, is provided with the second and third power supply lines for supplying the second power supply voltage. The metal interconnect layer above the first to sixth transistors is provided with the first and second lines corresponding to the first and second bit lines, respectively, and the first power supply line for supplying the first power supply voltage. Accordingly, the lines formed in the first back interconnect layer are only the power supply lines for supplying the second power supply voltage. It is thus possible to increase the line widths of the power supply lines in the first back interconnect layer and reduce the line resistances of the power supply lines, which can reduce lowering of the operating speed of the semiconductor memory device.

Further, since it is not necessary to form the power supply lines for supplying the second power supply voltage in the metal interconnect layer, the line width of the first line can be increased. This can reduce the line resistances of the bit lines and thus can reduce lowering of the operating speed of the semiconductor memory device.

Forming the power supply lines for supplying the first power supply voltage between the first line and the second line reduces the crosstalk noise between the first and second lines, which can reduce degradation in the performance and decrease in the reliability of the semiconductor memory device.

Due to formation of the line, corresponding to the word line, in a layer above the metal interconnect layer, no connector is required in connecting the lines on the back of the transistor and the lines on the front of the transistor (i.e., layer above the transistor), making it possible to reduce lowering of the operating speed of the semiconductor memory device, while reducing an increase in the area of the semiconductor memory device.

The present disclosure provides a layout structure of an SRAM cell with a line on the back of a transistor, which can reduce an increase in the area of a semiconductor memory device, while reducing lowering of the operating speed of the semiconductor memory device.

### BRIEF DESCRIPTION OF THE DRAWINGS

FIG. 1 is a plan view of an example layout structure of an SRAM cell according to a first embodiment.

FIG. 2 is a cross-sectional view of the example layout structure of the SRAM cell according to the first embodiment.

FIG. 3 is another cross-sectional view of the example layout structure of the SRAM cell according to the first embodiment.

FIG. 4 is a circuit diagram showing a configuration of the SRAM cell according to the first embodiment.

FIGS. 5A and 5B illustrate another configuration example of a semiconductor integrated circuit device according to the first embodiment.

FIG. 6 is a plan view of another example layout structure of the SRAM cell according to the first embodiment.

FIG. 7 is a plan view of another example layout structure of the SRAM cell according to the first embodiment.

FIG. 8 is a plan view showing an example layout of a circuit block in the semiconductor integrated circuit device according to the first embodiment.

FIG. 9 is a plan view showing another example layout of the circuit block in the semiconductor integrated circuit device according to the first embodiment.

FIG. 10 is a plan view of an example layout structure of an SRAM cell according to a second embodiment.

FIG. 11 is a plan view of another example layout structure of the SRAM cell according to the second embodiment.

### DETAILED DESCRIPTION

Embodiments will be described in detail with reference to the drawings. The following embodiments assume a semiconductor memory device including a plurality of SRAM cells, at least some of which include a nanosheet FET. The nanosheet FET is an FET using a thin sheet (nanosheet) through which current flows. The nanosheet is made of silicon, for example. In the present disclosure, the transistors included in the SRAM cells are not limited to the nanosheet FETs.

In this specification, “VDD” and “VSS” indicate power supply voltages or power sources themselves. In this specification, expressions indicating that the widths and the like are the same, such as “the same line width,” shall be understood to include manufacturing tolerances.

### First Embodiment

### Configuration of SRAM Cell

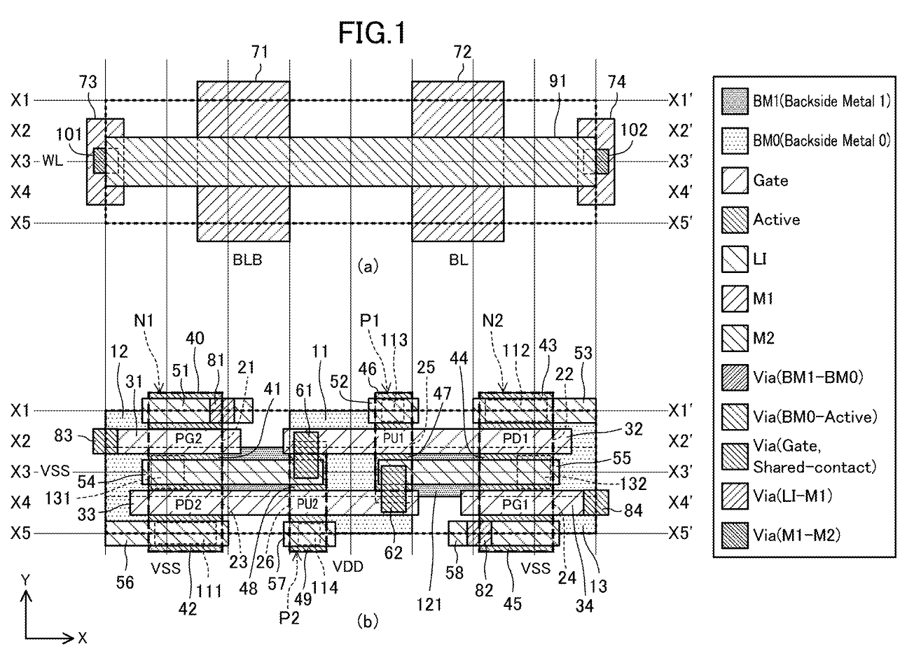

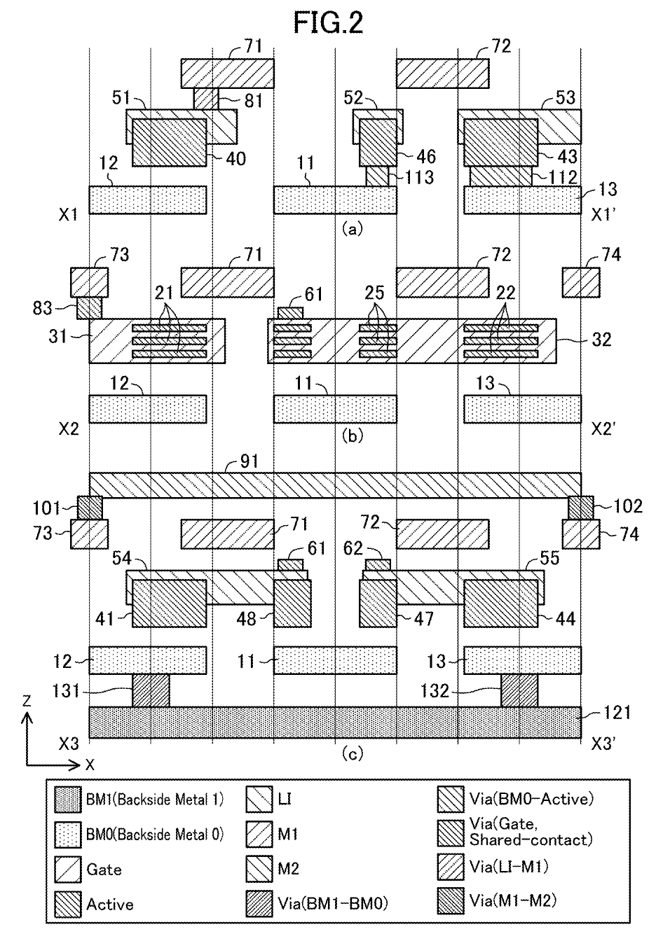

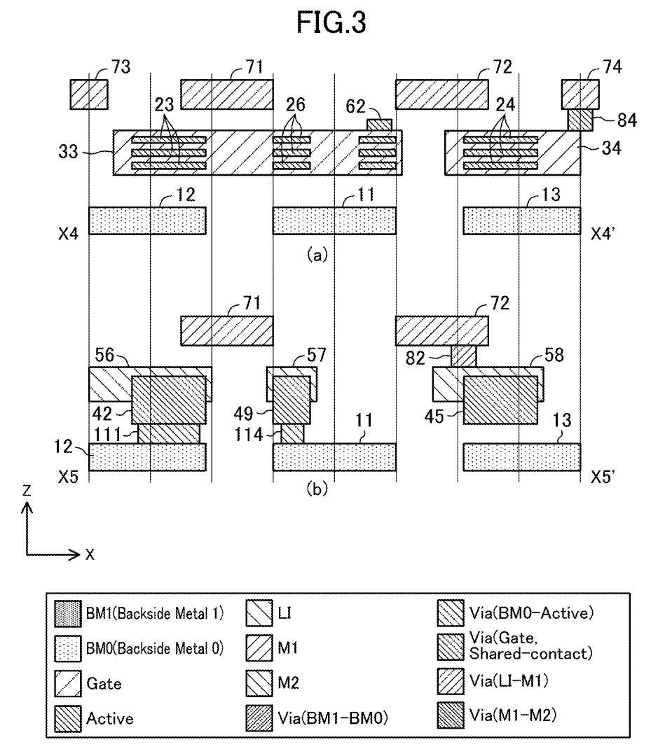

FIGS. 1 to 3 illustrate an example layout structure of an SRAM cell according to a first embodiment. (a) and (b) in FIG. 1 are plan views. (a) to (c) in FIG. 2 and (a) and (b) in FIG. 3 are cross-sectional views along the lateral direction of the plan view. Specifically, in FIG. 1, (a) illustrates a cell upper portion which includes M1, M2 interconnect layers, and (b) illustrates a cell lower portion which is a layer below the M1, M2 interconnect layers and includes a nanosheet FET. In FIG. 2, (a) illustrates a section taken along line X1-X1’; (b) illustrates a section taken along line X2-X2’; and (c) illustrates a section taken along line X3-X3’. In FIG. 3, (a) illustrates a section taken along line X4-X4’, and (b) illustrates a section taken along line X5-X5’.

In the following description, the up-and-down direction of the drawing showing the plan view, such as FIG. 1, will be referred to as the Y-direction (first direction), the lateral direction (second direction) of the drawing as the X-direction, and the direction perpendicular to the substrate surface as the Z-direction.

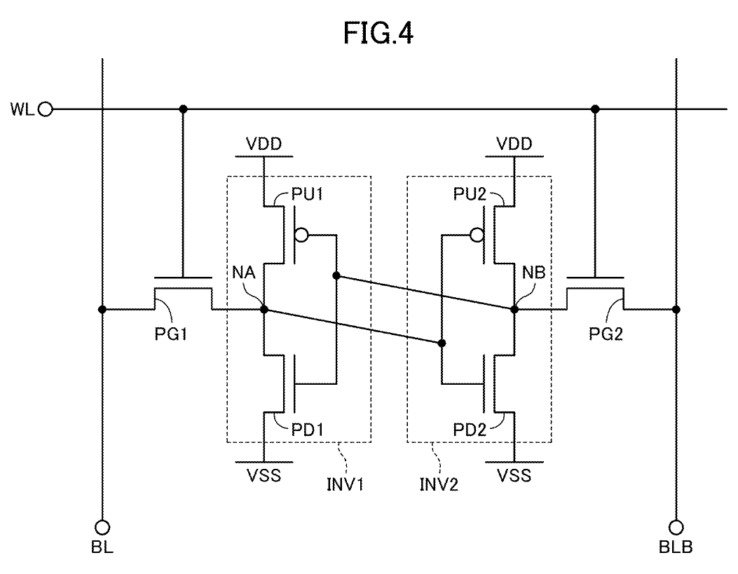

FIG. 4 is a circuit diagram showing a configuration of the SRAM cell according to the first embodiment. As shown in FIG. 4, the SRAM cell includes an SRAM circuit configured with load transistors PU1 and PU2, drive transistors PD1 and PD2, and access transistors PG1 and PG2. The load transistors PU1 and PU2 are each a P-type FET. The drive transistors PD1 and PD2 and the access transistors PG1 and PG2 are each an N-type FET.

The load transistor PU1 is provided between a power source VDD and a first node NA, and the drive transistor PD1 is provided between the first node NA and a power source VSS. The load transistor PU1 and the drive transistor PD1 have their gates connected to a second node NB to configure an inverter INV1. The load transistor PU2 is provided between the power source VDD and the second node NB, and the drive transistor PD2 is provided between the second node NB and the power source VSS. The load transistor PU2 and the drive transistor PD2 have their gates connected to the first node NA to configure an inverter INV2. That is, the output of one inverter is connected to the input of the other inverter, whereby a latch is formed.

The access transistor PG1 is provided between a bit line BL and the first node NA, and has a gate connected to a word line WL. The access transistor PG2 is provided between a bit line BLB and the second node NB, and has a gate connected to the word line WL. The bit lines BL and BLB constitute a complementary bit line pair.

In the SRAM circuit, if the bit lines BL and BLB forming the complementary bit line pair are driven to a high level and a low level, respectively, and the word line WL is driven to a high level, the high level is written to the first node NA and the low level is written to the second node NB. In contrast, if the bit lines BL and BLB are driven to a low level and a high level, respectively, and the word line WL is driven to a high level, the low level is written to the first node NA and the high level is written to the second node NB. Then, if the word line WL is driven to a low level with the data being written to the first and second nodes NA and NB, a latch state is determined and the data written to the first and second nodes NA and NB is retained.

If the bit lines BL and BLB are pre-charged to a high level and the word line WL is driven to a high level, the state of each of the bit lines BL and BLB is determined according to the data written to the first and second nodes NA and NB, and thus data can be read out from the SRAM cell. Specifically, if the first node NA is at a high level and the second node NB is at a low level, the bit line BL is held at a high level and the bit line BLB is discharged to a low level. In contrast, if the first node NA is at a low level and the second node NB is at a high level, the bit line BL is discharged to a low level and the bit line BLB maintains a high level.

As described above, the SRAM cell controls the bit lines BL and BLB and the word line WL, providing functions of writing data in the SRAM cell, retaining data, and reading out data from the SRAM cell.

In the following description, solid lines running longitudinally and laterally in the plan view shown, for example, in FIG. 1 and solid lines running longitudinally in the sectional view shown, for example, in FIG. 2 indicate grids used for arranging components at the time of designing. The grids are arranged at equal intervals in the X-direction, and are arranged at equal intervals in the Y-direction. The intervals of the grids in the X-direction and those in the Y-direction may be the same or different. The intervals of the grids may be different among layers. Further, each component is not necessarily disposed on the grid.

Dotted lines surrounding the cell in the plan view shown, for example, in FIG. 1 indicate a cell frame of the SRAM cell (outer edge of the SRAM cell). The SRAM cell is disposed such that its cell frame comes into contact with a cell frame of an adjacent cell in the X-direction or the Y-direction.

In the plan view shown, for example, in FIG. 1, the SRAM cells inverted in the X-direction are arranged on both sides of the SRAM cell in the X-direction. The SRAM cells inverted in the Y-direction are arranged on both sides of the SRAM cell in the Y-direction.

As shown in (b) in FIG. 1, a backside metal 0 (BM0) interconnect layer and a backside metal 1 (BM1) interconnect layer, which are interconnect layers, are formed on the back of the semiconductor chip where a transistor is formed. The BM1 interconnect layer is provided below the BM0 interconnect layer, that is, farther from the transistor. The BM0 interconnect layer corresponds to a first back interconnect layer, and the BM1 interconnect layer corresponds to a second back interconnect layer.

The BM0 interconnect layer is provided with power supply lines 11 to 13 extending in the Y-direction between both the upper and lower ends of the cell. The power supply line 11 supplies the power supply voltage VDD. The power supply lines 12 and 13 supply the power supply voltage VSS.

The BM1 interconnect layer is provided with a power supply line 121 extending in the X-direction between both the right and left ends of the cell. The power supply line 121 supplies the power supply voltage VSS. The power supply line 121 is connected to the power supply line 12 through a via 131 and connected to the power supply line 13 through a via 132.

A plurality of active regions forming the channel, the source, and the drain of an N-type transistor are formed in an N-type transistor region on a P-type substrate (PSub) (not shown). Specifically, active regions N1 and N2 are formed in the N-type transistor region. The active regions N1 and N2 overlap the power supply lines 12 and 13, respectively, in plan view.

In the N-type transistor region, the access transistor PG2, the drive transistor PD1, the drive transistor PD2, and the access transistor PG1 are formed. The access transistor PG2, the drive transistor PD1, the drive transistor PD2, and the access transistor PG1 have, as a channel, nanosheets 21 to 24, respectively, each of which has a triple-sheet structure overlapping one another in plan view and extends in the Y-direction. That is, the access transistor PG2, the drive transistor PD1, the drive transistor PD2, and the access transistor PG1 are nanosheet FETs.

In the active region N1, the portion (i.e., a region 42) to serve as the source of the drive transistor PD2 is connected to the power supply line 12 through a via 111 provided at a position overlapping the power supply line 12 in plan view. In the active region N2, the portion (i.e., a region 43) to serve as the source of the drive transistor PD1 is connected to the power supply line 13 through a via 112 provided at a position overlapping the power supply line 13 in plan view.

A plurality of active regions forming the channel, the source, and the drain of a P-type transistor are formed in a P-type transistor region on an N-type well (NWell). Specifically, active regions P1 and P2 are formed in the P-type transistor region. The active regions P1 and P2 overlap the power supply line 11 in plan view.

In the P-type transistor region, the load transistors PU1 and PU2 are formed. The load transistors PU1 and PU2 have, as a channel, nanosheets 25 and 26, respectively, each of which has a triple-sheet structure overlapping one another in plan view and extends in the Y-direction. That is, the load transistors PU1 and PU2 are nanosheet FETs. The nanosheets 21 to 24 have a width in the X-direction twice the width of the nanosheets 25 and 26 in the X-direction.

In the active region, the portions to serve as the source and the drain on both sides of the nanosheets are formed by epitaxial growth of the nanosheets, for example.

In the active region P1, the portion (i.e., a region 46) to serve as the source of the load transistor PU1 is connected to the power supply line 11 through a via 113 provided at a position overlapping the power supply line 11 in plan view. In the active region P2, the portion (i.e., a region 49) to serve as the source of the load transistor PU2 is connected to the power supply line 11 through a via 114 provided at a position overlapping the power supply line 11 in plan view.

As shown in (b) of FIG. 1, gate lines (Gate) 31 to 34 extending in the X-direction are formed. The gate line 31 surrounds the outer periphery of the nanosheet 21 in the X-direction and the Z-direction. The gate line 32 surrounds the outer periphery of the nanosheets 25 and 22 in the X-direction and the Z-direction. The gate line 33 surrounds the outer periphery of the nanosheets 23 and 26 in the X-direction and the Z-direction. The gate line 34 surrounds the outer periphery of the nanosheet 24 in the X-direction and the Z-direction. The gate line 31 corresponds to the gate of the access transistor PG2. The gate line 32 corresponds to the gates of the load transistor PU1 and the drive transistor PD1. The gate line 33 corresponds to the gates of the drive transistor PD2 and the load transistor PU2. The gate line 34 corresponds to the gate of the access transistor PG1.

The local interconnect layer is provided with local lines 51 to 58 extending in the X-direction. The local line 51 is connected to a region 40 in the active region N1. The local line 52 is connected to the region 46 in the active region P1. The local line 53 is connected to the region 43 in the active region N2. The local line 54 is connected to a region 41 in the active region N1 and a region 48 in the active region P2. The local line 55 is connected to a region 47 in the active region P1 and a region 44 in the active region N2. The local line 56 is connected to the region 42 in the active region N1. The local line 57 is connected to the region 49 in the active region P2. The local line 58 is connected to a region 45 in the active region N2.

The region 40 is a portion of the active region N1 that serves as the source of the access transistor PG2. The region 41 is a portion of the active region N1 that serves as the drain of the access transistor PG2 and the drain of the drive transistor PD2. The region 42 is a portion of the active region N1 that serves as the source of the drive transistor PD2. The region 43 is a portion of the active region N2 that serves as the source of the drive transistor PD1. The region 44 is a portion of the active region N2 that serves as the drain of the drive transistor PD1 and the drain of the access transistor PG1. The region 45 is a portion of the active region N2 that serves as the source of the access transistor PG1. The region 46 is a portion of the active region P1 that serves as the source of the load transistor PU1. The region 47 is a portion of the active region P1 that serves as the drain of the load transistor PU1. The region 48 is a portion of the active region P2 that serves as the drain of the load transistor PU2. The region 49 is a portion of the active region P2 that serves as the source of the load transistor PU2.

The local line 54 is connected to the gate line 32 through a shared-contact 61. The local line 55 is connected to the gate line 33 through a shared-contact 62. The gate line 33, the local line 55, and the shared-contact 62 correspond to the first node NA. The gate line 32, the local line 54, and the shared-contact 61 correspond to the second node NB.

As shown in (a) in FIG. 1, the M1 interconnect layer, which is a metal interconnect layer above the local interconnect layer, is provided with lines 71 and 72 extending in the Y-direction between both the upper and lower ends of the cell in the drawing. Further, lines 73 and 74 are formed. The lines 71 and 72 correspond to the bit lines BLB and BL. The line 71 includes portions overlapping the active region N1 and the power supply line 12 in plan view. The line 72 includes portions overlapping the active region N2 and the power supply line 13 in plan view.

The line 71 is connected to the local line 51 through a via 81. The line 72 is connected to the local line 58 through a via 82. The line 73 is connected to the gate line 31 through a contact (Gate-contact) 83. The line 74 is connected to the gate line 34 through a contact 84.

A line 91 extending in the X-direction from the left end to the right end of the cell in the drawing is formed in the M2 interconnect layer located above the M1 interconnect layer. The line 91 corresponds to the word line WL. The line 91 is connected to the line 73 through a via 101, and is connected to the line 74 through a via 102.

With the above configuration, the BM0 interconnect layer, which is an interconnect layer on the backs of the transistors, is provided with the power supply line 11 for supplying the power supply voltage VDD and the power supply lines 12 and 13 for supplying the power supply voltage VSS. The lines 71 and 72 corresponding to bit lines BLB and BL, respectively, are formed in the M1 interconnect layer, which is the metal interconnect layer above the transistors. Accordingly, the lines formed in the BM0 interconnect layer are only the power supply lines for supplying the power supply voltages VDD and VSS. This can increase the line widths of the power supply lines 11 to 13, formed in the BM0 interconnect layer, for supplying the power supply voltages VDD and VSS; it is thus possible to reduce the line resistances of the power supply lines. The power supply line 11 overlaps the active regions P1 and P2 in plan view, and is connected to the active regions P1 and P2 at the vias 113 and 114 provided in the overlapping region. The power supply line 12 overlaps the active region N1 in plan view, and is connected to the active region N1 through the via 111 provided in the overlapping region. The power supply line 13 overlaps the active region N2 in plan view, and is connected to the active region N2 through the via 112 provided in the overlapping region. Accordingly, the resistance values of the power supply paths of the power supply voltages VDD and VSS to the active regions can be reduced. The configuration described above can reduce lowering of the operating speed of the semiconductor memory device and increase the stability of the operation. Since it is not necessary to form the power supply lines for supplying the power supply line voltages VDD and VSS in the M1 interconnect layer, the line widths of the lines 71 and 72 corresponding to the bit lines BLB and BL, respectively, can be increased. This can reduce the line resistances of the bit lines and thus can reduce lowering of the operating speed of the semiconductor memory device.

The M2 interconnect layer above the M1 interconnect layer is provided with the line 91 corresponding the word line WL. Accordingly, no connector is required in connecting the lines on the back of the transistor and the lines on the front of the transistor (i.e., layer above the transistor), making it possible to reduce lowering of the operating speed of the semiconductor memory device, while reducing an increase in the area of the semiconductor memory device.

The power supply lines on the back of the transistors described above may be configured using a semiconductor chip different from the semiconductor chip in which the transistor is formed.

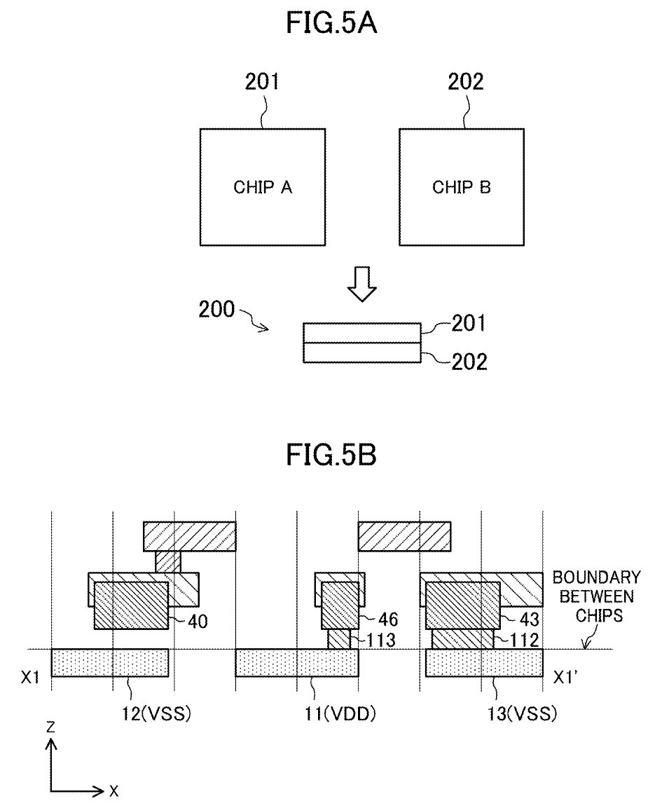

FIG. 5A shows a configuration example of a semiconductor integrated circuit device according to the first embodiment. A semiconductor integrated circuit device 200 shown in FIG. 5A is formed of a first semiconductor chip 201 (i.e., a chip A) and a second semiconductor chip 202 (i.e., a chip B) stacked on each other. The SRAM cell and other components described above are arranged on the chip A. The chip B is provided with the power supply lines in an interconnect layer on the front. The chip B is bonded to the back of the chip A, using bumps or other means.

FIG. 5B shows a cross section of the SRAM cell of FIG. 1 taken along the line X1-X1’ according to this configuration example. As shown in FIG. 5B, the interconnect layer on the front of the chip B is provided with the power supply line 11 for supplying VDD and the power supply lines 12 and 13 for supplying VSS. The power supply line 11 is connected to the region 46 of the chip A through the via 113 provided at a position overlapping the power supply line 11 in plan view. The power supply line 13 is connected to the region 43 of the chip A through the via 112 provided at a position overlapping the power supply line 13 in plan view. Although not shown, the power supply line 12 is connected to the region 42 of the chip A through the via 111 provided at a position overlapping the power supply line 12 in plan view.

### First Variation

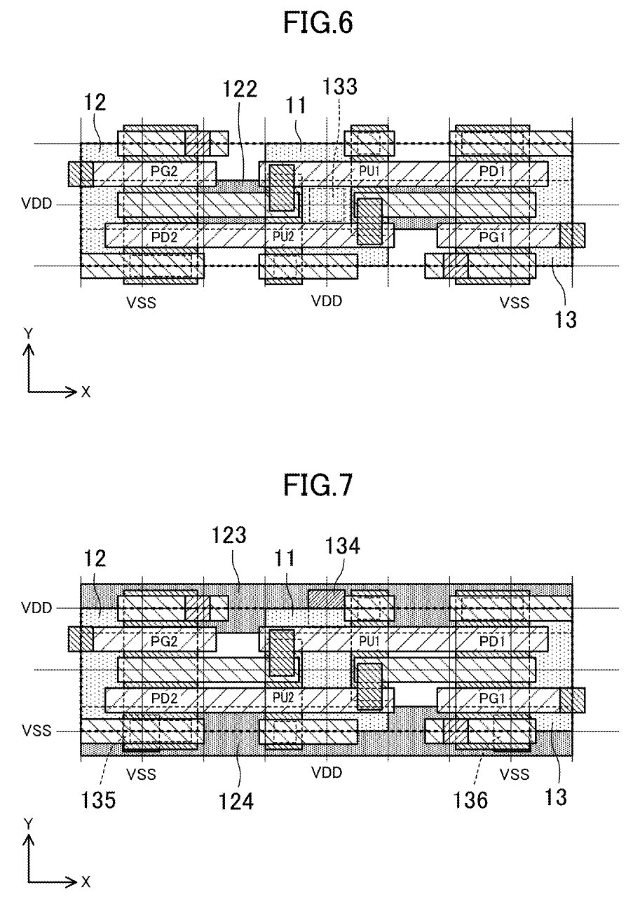

FIG. 6 is a plan view of another example layout structure of the SRAM cell according to the first embodiment. Specifically, FIG. 6 shows the cell lower portion. The cell upper portion in FIG. 6 is the same as that in (a) of FIG. 1.

In FIG. 6, as compared with FIG. 1, a power supply line 122 extending in the X-direction is formed in the BM0 interconnect layer instead of the power supply line 121. The power supply line 122 supplies the power supply voltage VDD. The power supply line 122 is connected to the power supply line 11 through a via 133.

The configuration in FIG. 6 can enhance the power supply voltage VDD supplied to the SRAM cells. In addition, the advantages similar to those of FIG. 1 can be obtained.

### Second Variation

FIG. 7 is a plan view of another example layout structure of the SRAM cell according to the first embodiment. Specifically, FIG. 7 shows the cell lower portion. The cell upper portion in FIG. 7 is the same as that in (a) of FIG. 1.

In FIG. 7, as compared with FIG. 1, power supply lines 123 and 124 extending in the X-direction are formed in the BM0 interconnect layer instead of the power supply line 121. The power supply line 123 is formed at the upper end of the drawing and supplies the power supply voltage VDD. The power supply line 124 is formed at the lower end of the drawing and supplies the power supply voltage VSS. The power supply line 123 is connected to the power supply line 11 through a via 134. The power supply line 124 is connected to the power supply line 12 through a via 135 and connected to the power supply line 13 through a via 136.

The configuration in FIG. 7 can enhance the power supply voltages VDD and VSS supplied to the SRAM cells. In addition, the advantages similar to those of FIG. 1 can be obtained.

### Configuration of Circuit Block

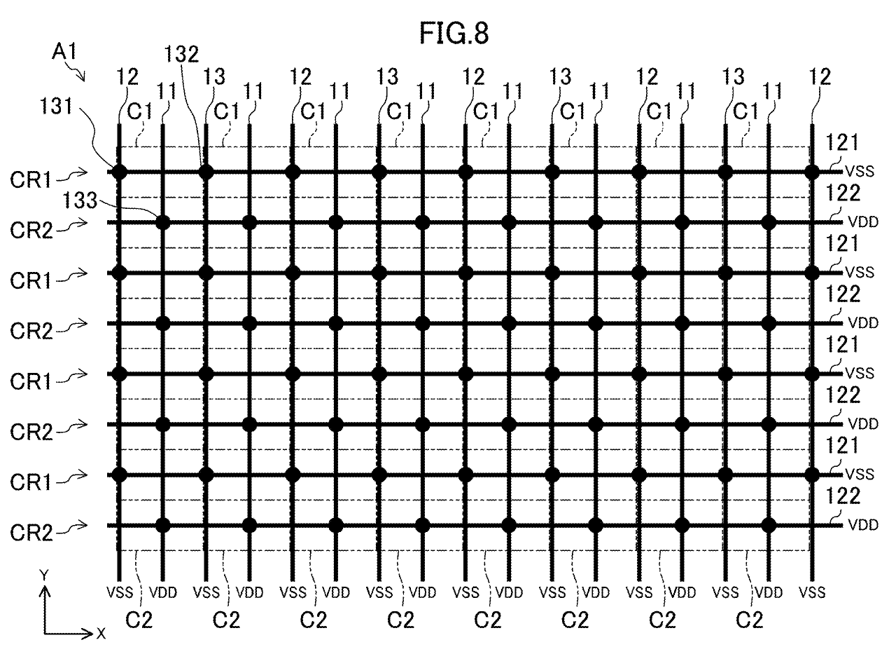

FIG. 8 is another plan view showing the example layout of the circuit block in the semiconductor integrated circuit device according to the embodiment. In FIG. 8, only the cell frames of the SRAM cells, the power supply lines formed in the BM0 interconnect layer and the BM1 interconnect layer, and the vias connecting the power supply lines are shown, and the internal structure of the SRAM cells, the lines between the SRAM cells, and other configurations are not shown.

In the block layout shown in FIG. 8, a memory cell array A1 is formed. In the memory cell array A1, cell rows CR1 and cell rows CR2 are aligned alternately in the Y-direction. Each cell row CR1 includes a plurality of SRAM cells C1 aligned in the X-direction. Each cell row CR2 includes a plurality of SRAM cells C2 aligned in the X-direction. Each of the SRAM cells C1 is the SRAM cell of FIG. 1. Each of the SRAM cells C2 is the SRAM cell shown in FIG. 6 inverted in the Y-direction.

As shown in FIG. 8, in the BM0 interconnect layer, the SRAM cells C1 and C2 aligned in the Y-direction are connected in common to the power supply line 12 (13) extending in the Y-direction for supplying the power supply voltage VSS. In the BM0 interconnect layer, the SRAM cells C1 and C2 aligned in the Y-direction are connected in common to the power supply line 11 extending in the Y-direction for supplying the power supply voltage VDD. The power supply lines 12 (13) for supplying the power supply voltage VSS and the power supply lines 11 for supplying the power supply voltage VDD are arranged alternately in the X-direction. In the BM1 interconnect layer, the SRAM cells C1 arranged in each cell row CR1 are connected in common to the power supply line 121 extending in the X-direction for supplying the power supply voltage VSS. In the BM1 interconnect layer, the SRAM cells C2 arranged in each cell row CR2 are connected in common to the power supply line 122 extending in the X-direction for supplying the power supply voltage VDD. The power supply line 121 for supplying the power supply voltage VSS and the power supply line 122 for supplying the power supply voltage VDD are arranged alternately in the Y-direction. That is, the BM0 interconnect layer and the BM1 interconnect layer are provided with mesh-like power supply lines for supplying the power supply voltages VDD and VSS. Thus, the line resistance of the lines supplying the power supply voltage decreases, which reduces the fluctuation of the power supply voltage; it is thus possible to reduce lowering of the operating speed of the semiconductor memory device and increase the stability of the operation.

In the example of FIG. 8, the cell rows CR1 and the cell rows CR2 are aligned alternately in the Y-direction, but are not limited thereto. For example, each cell row CR2 may be arranged after every N cell rows CR1 in the Y-direction, where N is an integer of three or more.

In the example of FIG. 8, eight SRAM cells are arranged in the X-direction, and eight SRAM cells are aligned in the Y-direction; however, the number of SRAM cells arranged in the X-direction and the Y-direction is not limited thereto.

### Variation

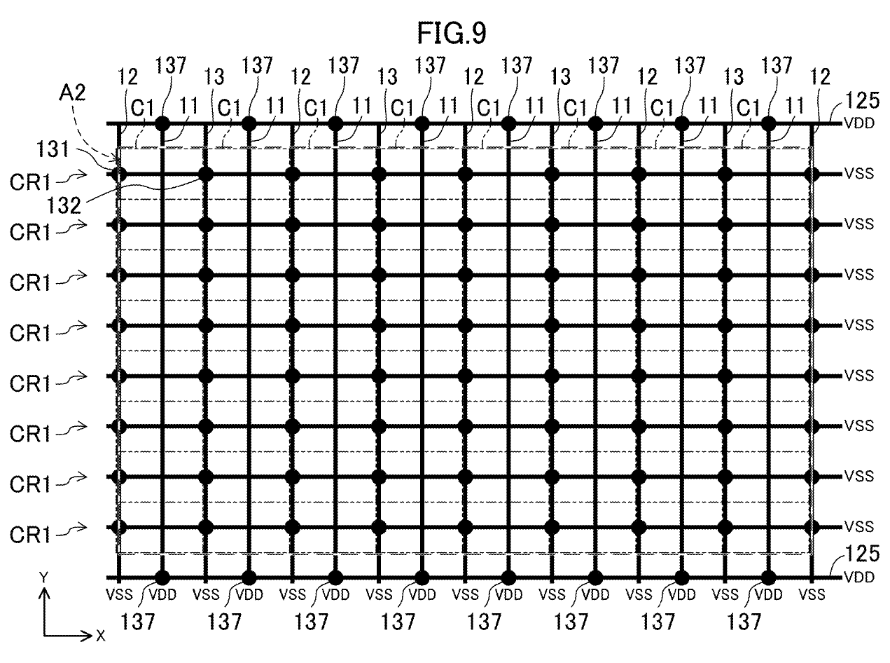

FIG. 9 is a plan view showing another example layout of the circuit block in the semiconductor integrated circuit device according to the embodiment. In FIG. 9, similarly to FIG. 8, only the cell frames of the SRAM cells, the power supply lines formed in the BM0 interconnect layer and the BM1 interconnect layer, and the vias connecting the power supply lines are shown, and the internal structure of the SRAM cells, the lines between the SRAM cells, and other configurations are not shown.

In the block layout shown in FIG. 9, a memory cell array A2 is formed. In the memory cell array A2, a plurality of cell rows CR1 are aligned in the Y-direction. Each cell row CR1 includes a plurality of SRAM cells C1 aligned in the X-direction. Each of the SRAM cells C1 is the SRAM cell of FIG. 1.

As shown in FIG. 9, in the BM1 interconnect layer inside the memory cell array A2, the SRAM cells C1 arranged in each cell row CR1 are connected in common to the power supply line 121 extending in the X-direction for supplying the power supply voltage VSS. Multiple power supply lines 121 are aligned in the X-direction. Accordingly, only the power supply lines for supplying the power supply voltage VSS are formed in the BM1 interconnect layer in the memory cell array A2.

Power supply lines 125 extending in the X-direction are formed outside the memory cell array A2 (e.g., in a well tap region or a dummy memory region). The power supply lines 125 are formed in the BM1 interconnect layer and supply the power supply voltage VDD. In the example of FIG. 9, the power supply lines 125 are formed above the uppermost cell row CR1 in the drawing and below the lowermost cell row CR1 in the drawing. The power supply lines 125 are connected to the respective power supply lines 11 extending in the Y-direction, through vias 137.

According to the variation, the BM0 interconnect layer and the BM1 interconnect layer are provided with mesh-like power supply lines for supplying the power supply voltages VSS and VDD. Thus, the line resistance of the lines supplying the power supply voltage decreases, which reduces the fluctuation of the power supply voltage; it is thus possible to reduce lowering of the operating speed of the semiconductor memory device and increase the stability of the operation.

### Second Embodiment

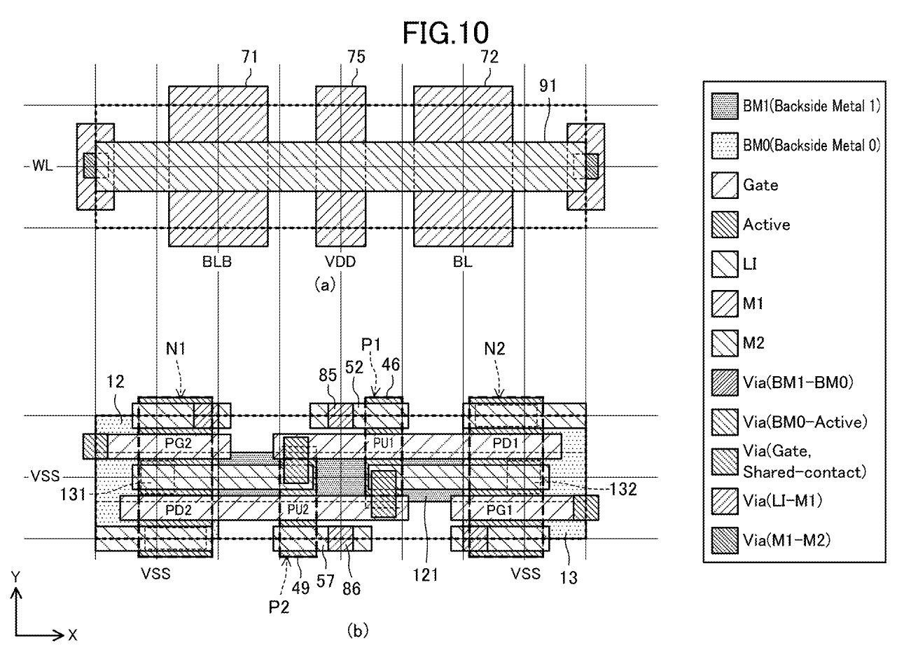

FIG. 10 is a plan view of an example layout structure of an SRAM cell according to a second embodiment. Specifically, in FIG. 10, (a) shows a cell upper portion, and (b) shows a cell lower portion. In FIG. 10, as compared with FIG. 1, the power supply line 11 in the BM0 interconnect layer is omitted, and a power supply line 75 is formed in the M1 interconnect layer.

Specifically, the M1 interconnect layer is provided with the power supply line 75 extending in the Y-direction between both the upper and lower ends of the cell. The power supply line 75 supplies the power supply voltage VDD. The power supply line 75 is formed between the line 71 and the line 72.

The power supply line 75 is connected to the portion (i.e., the region 46) to serve as the source of the load transistor PU1 through a via 85 provided at a position overlapping the power supply line 75 in plan view. The power supply line 75 is connected to the portion (i.e., the region 49) to serve as the source of the load transistor PU2 through a via 86 provided at a position overlapping the power supply line 75 in plan view.

With the above configuration, the BM0 interconnect layer, which is an interconnect layer on the back of the transistors, is provided with the power supply lines 12 and 13 for supplying the power supply voltage VSS. The M1 interconnect layer, which is a metal interconnect layer above the transistor, is provided with the lines 71 and 72 corresponding to the bit lines BLB and BL, respectively, and the power supply line 75 for supplying the power supply voltage VDD. Accordingly, the lines formed in the BM0 interconnect layer are only the power supply lines for supplying the power supply voltage VSS. Accordingly, the line widths of the power supply lines (i.e., the power supply lines 12 and 13) for supplying the power supply voltage VSS in the BM0 interconnect layer can be increased, which can reduce the line resistances of the power supply lines and reduce the fluctuation of the power supply voltage, thereby making it possible to reduce lowering of the operating speed of the semiconductor memory device and increase the stability of the operation.

Since it is not necessary to form the power supply lines for supplying the power supply line voltage VSS in the M1 interconnect layer, the line widths of the lines 71 and 72 corresponding to the bit lines BLB and BL, respectively, can be increased. This can reduce the line resistances of the bit lines and thus can reduce lowering of the operating speed of the semiconductor memory device.

The power supply line 75 for supplying the power supply voltage VDD is formed between the line 71 and the line 72. This reduces the crosstalk noise between the lines 71 and 72 corresponding to the bit lines BLB and BL, respectively, which can reduce degradation in the performance and decrease in the reliability of the semiconductor memory device.

The M2 interconnect layer above the M1 interconnect layer is provided with the line 91 corresponding the word line WL. Accordingly, no connector is required in connecting the lines on the back of the transistor and the lines on the front of the transistor (i.e., layer above the transistor), making it possible to reduce lowering of the operating speed of the semiconductor memory device, while reducing an increase in the area of the semiconductor memory device.

In addition, the advantages similar to those of FIG. 1 can be obtained.

### Variation

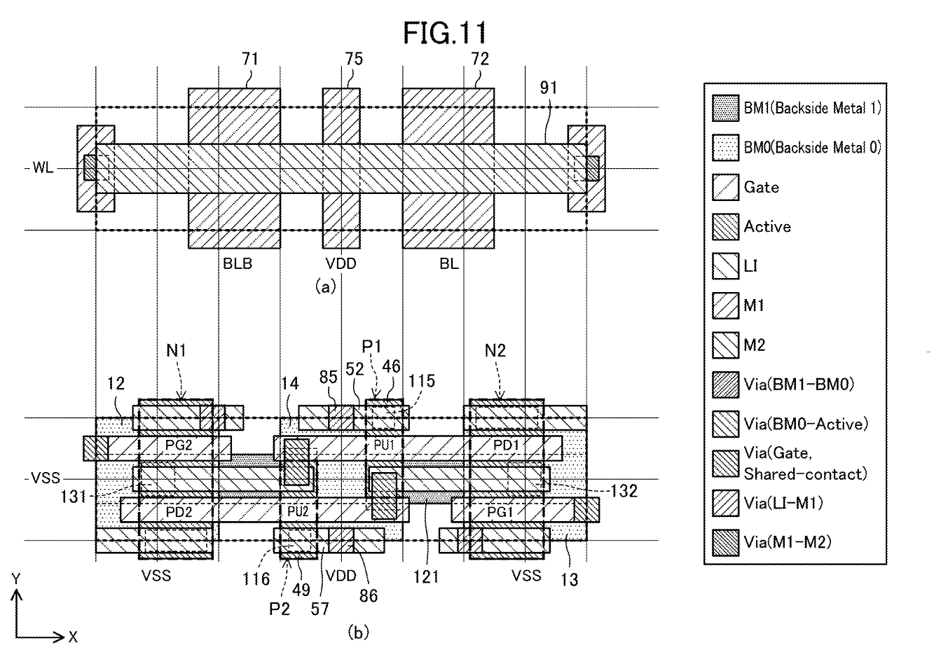

FIG. 11 is a plan view of another example layout structure of the SRAM cell according to the second embodiment. Specifically, in FIG. 11, (a) illustrates a cell upper portion, and (b) illustrates a cell lower portion. As compared with FIG. 10, a power supply line 14 is formed in the BM0 interconnect layer in FIG. 11.

Specifically, the BM0 interconnect layer is provided with the power supply line 14 extending in the Y-direction between both the upper and lower ends of the cell in the drawing. The power supply line 14 supplies the power supply voltage VDD. The power supply line 14 is formed between the power supply line 12 and the power supply line 13. The power supply line 14 overlaps the active regions P1 and P2 and the power supply line 75 in plan view.

The power supply line 14 is connected to the portion (i.e., the region 46) to serve as the source of the load transistor PU1 through a via 115 provided at a position overlapping the power supply line 14 in plan view. The power supply line 14 is connected to the portion (i.e., the region 49) to serve as the source of the load transistor PU2 through a via 116 provided at a position overlapping the power supply line 14 in plan view.

In the variation, the BM0 interconnect layer, which is an interconnect layer on the back of the transistors, is provided with the power supply line 14 for supplying the power supply voltage VDD. This can reduce the line width of the power supply line 75 formed in the M1 interconnect layer to supply the power supply voltage VDD; it is thus possible to reduce the line widths of the lines 71 and 72, while reducing the crosstalk noise between the lines 71 and 72 corresponding to the bit lines BLB and BL, respectively.

Since the power supply lines for supplying the power supply voltage VDD are formed in the M1 interconnect layer and the BM0 interconnect layer, it is possible to reduce the line width of the power supply line 14 formed in the BM0 interconnect layer. This can increase the line widths of the power supply lines 12 and 13 for supplying the power supply voltage VSS, reduce the line resistances of the power supply lines, and reduce the fluctuation of the power supply voltage. It is thus possible to reduce lowering of the operating speed of the semiconductor memory device, and increase the stability of the operation.

In addition, the advantages similar to those of FIG. 10 can be obtained.

In this variation, the power supply line 121 for supplying the power supply voltage VSS is formed in the BM1 interconnect layer, but is not limited thereto. In place of the power supply line 121, a power supply line for supplying the power supply voltage VDD may be formed in the BM1 interconnect layer. In this case, as in FIG. 6, this power supply line may be connected to the power supply line 14 of the BM0 interconnect layer. In addition to the power supply line 121, power supply lines for supplying the power supply voltage VDD and the power supply voltage VSS may be formed in the BM1 interconnect layer. In this case, as in FIG. 7, a power supply line for supplying the power supply voltage VDD may be connected to the power supply line 14, and a power supply line for supplying the power supply voltage VSS may be connected to the power supply lines 12 and 13.

In the above embodiments and variations, each transistor includes three nanosheets, but some or all of the transistors may include one, two, four, or more nanosheets.

In the above embodiments and variations, the sectional shape of the nanosheet is rectangular, but is not limited thereto. For example, the shape may be square, circular, or elliptical.

In the above embodiments and variations, the widths of the nanosheets 21 to 24 in the X-direction is twice the widths of the nanosheets 25 and 26 in the X-direction, but are not limited thereto. The widths of the nanosheets 21 to 26 in the X-direction may be determined in view of the operational stability and other capabilities of the SRAM circuit.

In the above embodiment and variations, the shared-contacts 61 and 62 may be manufactured in the same process as that for the contacts (Gate-Contact) and the local lines, or may be manufactured in different processes.

In the embodiments and variations described above, the power source for supplying the power supply voltage VDD to the sources (the regions 46 and 49) of the load transistors PU1 and PU2 is not limited to the power source supplied from the outside of the semiconductor integrated circuit, and may be a power source generated inside the semiconductor integrated circuit, a power source generated inside the semiconductor memory device, or any other suitable type of power source.

The present disclosure provides a layout structure of an SRAM cell with a line on the back of a transistor, which can reduce an increase in the area of a semiconductor memory device, while reducing lowering of the operating speed of the semiconductor memory device.

### DESCRIPTION OF REFERENCE CHARACTERS

11 to 14, 75 Power Supply Line

111 to 116 Via

21 to 26 Nanosheet

31 to 34 Gate Line

40 to 49 Region

71, 72 Line

PU1, PU2 Load Transistor

PD1, PD2 Drive Transistor

PG1, PG2 Access Transistor

BL, BLB Bit Line

WL Word Line

What is claimed is:

1. A semiconductor memory device including an SRAM cell,
the SRAM cell comprising:
a first transistor having a source connected to a first power source for supplying a first power supply voltage, a drain connected to a first node, and a gate connected to a second node;
a second transistor having a source connected to the first power source, a drain connected to the second node, and a gate connected to the first node;
a third transistor having a source connected to a second power source for supplying a second power supply voltage different from the first power supply voltage, a drain connected to the first node, and a gate connected to the second node;
a fourth transistor having a source connected to the second power source, a drain connected to the second node, and a gate connected to the first node;
a fifth transistor having a source connected to a first bit line, a drain connected to the first node, and a gate connected to a word line; and
a sixth transistor having a source connected to a second bit line forming a complementary bit line pair together with the first bit line, a drain connected to the second node, and a gate connected to the word line,
the first bit line including a first line formed in a metal interconnect layer above the first to sixth transistors, the first line extending in a first direction,
the second bit line including a second line formed in the metal interconnect layer, the second line extending in the first direction,
the SRAM cell comprising:
a third active region forming a channel, the source, and the drain of the third transistor, and including a nanosheet extending in the first direction as the channel;
a fourth active region forming a channel, the source, and the drain of the fourth transistor, and including a nanosheet extending in the first direction as the channel;
a first power supply line formed in the metal interconnect layer, the first power supply line extending in the first direction and connected to the first power source;
a second power supply line formed in a first back interconnect layer on a back side of the first to sixth transistors, the second power supply line extending in the first direction, including a portion overlapping the third active region in plan view, and connected to the second power source;
a third power supply line formed in the first back interconnect layer, the third power supply line extending in the first direction, including a portion overlapping the fourth active region in plan view, and connected to the second power source;
a third via arranged at a position where a third region forming the source in the third active region and the second power supply line overlap each other, the third via connecting the third region and the second power supply line; and
a fourth via arranged at a position where a fourth region forming the source in the fourth active region and the third power supply line overlap each other, the fourth via connecting the fourth region and the third power supply line,
no other power supply line being formed between the second power supply line and the third power supply line in the first back interconnect layer.

2. The semiconductor memory device of claim 1, wherein
the SRAM cell further comprises a fourth power supply line formed in a second back interconnect layer below the first back interconnect layer, the fourth power supply line extending in a second direction perpendicular to the first direction and connected to the second power supply line and the third power supply line.

3. A semiconductor memory device including an SRAM cell,
the SRAM cell comprising:
a first transistor having a source connected to a first power source for supplying a first power supply voltage, a drain connected to a first node, and a gate connected to a second node;
a second transistor having a source connected to the first power source, a drain connected to the second node, and a gate connected to the first node;
a third transistor having a source connected to a second power source for supplying a second power supply voltage different from the first power supply voltage, a drain connected to the first node, and a gate connected to the second node;
a fourth transistor having a source connected to the second power source, a drain connected to the second node, and a gate connected to the first node;
a fifth transistor having a source connected to a first bit line, a drain connected to the first node, and a gate connected to a word line; and
a sixth transistor having a source connected to a second bit line forming a complementary bit line pair together with the first bit line, a drain connected to the second node, and a gate connected to the word line,
the first bit line including a first line formed in a metal interconnect layer above the first to sixth transistors, the first line extending in a first direction,
the second bit line including a second line formed in the metal interconnect layer, the second line extending in the first direction,
the SRAM cell comprising:
a first active region forming a channel, the source, and the drain of the first transistor, and including a nanosheet extending in the first direction as the channel;
a second active region forming a channel, the source, and the drain of the second transistor, and including a nanosheet extending in the first direction as the channel;
a third active region forming a channel, the source, and the drain of the third transistor, and including a nanosheet extending in the first direction as the channel;
a fourth active region forming a channel, the source, and the drain of the fourth transistor, and including a nanosheet extending in the first direction as the channel;
a first power supply line formed in a first back interconnect layer on a back side of the first to sixth transistors, the first power supply line extending in the first direction, including a portion overlapping the first active region and the second active region in plan view, and connected to the first power source;
a second power supply line formed in the first back interconnect layer, the second power supply line extending in the first direction, including a portion overlapping the third active region in plan view, and connected to the second power source;
a third power supply line formed in the first back interconnect layer, the third power supply line extending in the first direction, including a portion overlapping the fourth active region in plan view, and connected to the second power source;
a first via arranged at a position where a first region forming the source in the first active region and the first power supply line overlap each other, the first via connecting the first region and the first power supply line;
a second via arranged at a position where a second region forming the source in the second active region and the first power supply line overlap each other, the second via connecting the second region and the first power supply line;
a third via arranged at a position where a third region forming the source in the third active region and the second power supply line overlap each other, the third via connecting the third region and the second power supply line; and
a fourth via arranged at a position where a fourth region forming the source in the fourth active region and the third power supply line overlap each other, the fourth via connecting the fourth region and the third power supply line,
the semiconductor memory device further comprising a fourth power supply line formed in a second back interconnect layer below the first back interconnect layer, the fourth power supply line extending in a second direction perpendicular to the first direction.

4. The semiconductor memory device of claim 3, wherein
the fourth power supply line is connected to the second power supply line and the third power supply line.

5. The semiconductor memory device of claim 4, further comprising:
a fifth power supply line formed in the second back interconnect layer, the fifth power supply line extending in the second direction and connected to the first power supply line.

6. The semiconductor memory device of claim 3, wherein
the fourth power supply line is connected to the first power supply line.

7. The semiconductor memory device of claim 3 comprising:
a plurality of SRAM cells, each of the SRAM cells identical to the SRAM cell, wherein
the plurality of SRAM cells are aligned in the first direction and the second direction perpendicular to the first direction, and
the SRAM cells aligned in the first direction are connected in common to the same first power supply line and are connected in common to the same second power supply line.

8. The semiconductor memory device of claim 7, further comprising:
a plurality of fourth power supply lines formed in the second back interconnect layer, the fourth power supply lines extending in the second direction and connected to the second power source; and
a plurality of fifth power supply lines formed in the second back interconnect layer, the fifth power supply lines extending in the second direction and connected to the first power source, wherein
the plurality of SRAM cells include:
a first SRAM cell; and
a second SRAM cell,
first cell rows and second cell rows are aligned alternately in the first direction, each of the first cell rows including a plurality of first SRAM cells aligned in the second direction, each of the first SRAM cells being identical to the first SRAM cell, each of the second cell rows including a plurality of second SRAM cells aligned in the second direction, each of the second SRAM cells being identical to the second SRAM cell,
in each of the first cell rows, the second power supply line for each of the plurality of first SRAM cells is connected in common to the same fourth power supply line, and
in each of the second cell rows, the first power supply line for each of the plurality of second SRAM cells is connected in common to the same fifth power supply line.

9. The semiconductor memory device of claim 7, further comprising:
a plurality of fourth power supply lines formed in the second back interconnect layer below the first back interconnect layer, the fourth power supply lines extending in the second direction and connected to the second power source, wherein
a plurality of third cell rows, each including the plurality of SRAM cells aligned in the second direction, are aligned in the first direction,
in each of the third cell rows, the second power supply line for each of the plurality of SRAM cells is connected in common to the same fourth power supply line,
the second power supply line for each of the plurality of SRAM cells is connected to a sixth power supply line formed in the second back interconnect layer, the sixth power supply line extending in the second direction and connected to the first power source, and
a fifth power supply line is located outside the plurality of SRAM cells in plan view.
